(19) United States
(12) Patent Application Publication
(10) Pub. No.: US 2024/0266942 A1
(43) Pub. Date: Aug. 8, 2024

(54) CONTROL DEVICE, CONTROL SIGNAL GENERATION METHOD, AND VOLTAGE CONVERSION DEVICE

(71) Applicant: Chicony Electronics Co., Ltd., New Taipei City (TW)

(72) Inventor: Ming-Jang Yang, New Taipei City (TW)

(21) Appl. No.: 18/481,563

(22) Filed: Oct. 5, 2023

(30) Foreign Application Priority Data
Feb. 2, 2023 (TW) 112103729

(51) Int. Cl. H02M 1/08; H02J 7/00; H02M 3/156; H03K 3/037

(52) U.S. Cl. CPC H02M 1/08; H02J 7/0063; H02J 7/007182; H02M 3/156; H03K 3/037; H03K 5/00; H03K 2005/00078

(57) ABSTRACT

A control device, a control signal generation method and a voltage conversion device are provided. A delay circuit generates a delay signal based on a power signal. An output end of a logic circuit outputs a third level voltage in response to that the power signal or the battery signal is at a second level voltage. The output end outputs a fourth level voltage in response to that the power signal and the battery signal both are at a first level voltage. In response to that an output signal of the output end is the third level voltage, an output circuit outputs a level voltage of the received power signal when the delay signal is changed from the first level voltage to the second level voltage. The output circuit outputs a stopping voltage in response to that the output signal of the logic circuit is the fourth level voltage.

### CROSS-REFERENCE TO RELATED APPLICATION

This non-provisional application claims priority under 35 U.S.C. § 119(a) to Patent Application No. 112103729 filed in Taiwan, R.O.C. on Feb. 2, 2023, the entire contents of which are hereby incorporated by reference.

### BACKGROUND

### Technical Field

The instant disclosure is related to a control device and a control signal generation method, especially a control device and control signal generation method applicable to controlling DC conversion devices.

### Related Art

When a battery is providing power for an electronic system (such as a camera), if the charge of the battery is almost completely drained, during switching between heavy load and light load of the electronic system, the power supply of the battery often bounces and therefore can be unstable. This leads to malfunctioning of the electronic system.

### SUMMARY

As above, some embodiments of the instant disclosure provide a control device, a control signal generation method, and a voltage conversion device to resolve current technical problems.

Some embodiments of the instant disclosure provide a control device. The control device comprises a delay circuit, a logic circuit, and an output circuit. The delay circuit is configured to generate a delay signal based on a power signal. When the power signal is changed from a first level voltage to a second level voltage, the delay signal reaches the second level voltage later than the power signal. The logic circuit is configured to receive the power signal and a battery signal. An output end of the logic circuit outputs a third level voltage in response to that one of the power signal and the battery signal is at the second level voltage. The output end of the logic circuit outputs a fourth level voltage in response to that both of the power signal and the battery signal are at the first level voltage. The output circuit is configured to receive the power signal, the delay signal, and an output signal of the output end of the logic circuit. The output circuit, in response to that the output signal of the output end of the logic circuit is the third level voltage, when the delay signal is changed from the first level voltage to the second level voltage, outputs a level voltage of the power signal which is received. The output circuit outputs a stopping voltage in response to that the output signal of the output end of the logic circuit is the fourth level voltage.

Some embodiments of the instant disclosure provide a control signal generation method adapted for the aforementioned control device. The control signal generation method comprises the following steps: generating a delay signal by the delay circuit based on a power signal, wherein when the power signal is changed from a first level voltage to a second level voltage, the delay signal reaches the second level voltage later than the power signal; receiving the power signal and a battery signal by the logic circuit; outputting a third level voltage by an output end of the logic circuit in response to that one of the power signal and the battery signal is at the second level voltage; and outputting a fourth level voltage by the output end of the logic circuit in response to that both of the power signal and the battery signal are at the first level voltage; and receiving the power signal, the delay signal, and an output signal outputted by the output end of the logic circuit by the output circuit; in response to that the output signal of the output end of the logic circuit is the third level voltage, when the delay signal is changed from the first level voltage to the second level voltage, outputting a level voltage of the power signal which is received by the output circuit; and outputting a stopping voltage by the output circuit in response to that the output signal of the output end of the logic circuit is the fourth level voltage.

An embodiment of the instant disclosure provides a voltage conversion device comprising the aforementioned control device, a monitoring element, and a DC conversion element. The monitoring element is configured to monitor whether a battery of an electronic device is supplying power and output a battery usage signal based on an output voltage of the battery of the electronic device. The DC conversion element is configured to convert the output voltage provided by the battery in response to that the output circuit of the control device outputs a starting voltage and stop converting the output voltage provided by the battery in response to that the output circuit of the control device outputs the stopping voltage. The control device generates the battery signal based on the battery usage signal, and the control device generates the power signal based on a power input signal of the electronic device.

As above, by using sequential circuits which integrate the power signal, the power signal processed by the circuits, and the battery signal, the control device, the control signal generation method, and the voltage conversion device provided by some embodiments of the instant disclosure can generate control signals to timely stop the battery from supplying power using a simple circuit structure in order to maintain overall stability of an electronic system.

### BRIEF DESCRIPTION OF THE DRAWINGS

The instant disclosure will become more fully understood from the detailed description given herein below for illustration only, and thus not limitative of the instant disclosure, wherein:

FIG. 1 illustrates a schematic block diagram of a control device according to an embodiment of the instant disclosure.

FIG. 2 illustrates an operation sequence diagram of a control device according to an embodiment of the instant disclosure.

FIG. 3 illustrates a schematic block diagram of an output circuit according to an embodiment of the instant disclosure.

FIG. 4-1 illustrates a schematic circuit diagram of a logic circuit according to an embodiment of the instant disclosure.

FIG. 4-2 illustrates a schematic circuit diagram of a logic circuit according to an embodiment of the instant disclosure.

FIG. 5 illustrates a schematic circuit diagram of a delay circuit according to an embodiment of the instant disclosure.

FIG. 6 illustrates a schematic circuit diagram of a delay circuit according to an embodiment of the instant disclosure.

FIG. 7 illustrates a schematic block diagram of a control device according to an embodiment of the instant disclosure.

FIG. 8 illustrates a schematic diagram of a voltage conversion device according to an embodiment of the instant disclosure.

FIG. 9 illustrates a schematic flow chart of a control signal generation method according to an embodiment of the instant disclosure.

FIG. 10 illustrates a schematic flow chart of a control signal generation method according to an embodiment of the instant disclosure.

FIG. 11 illustrates a schematic flow chart of a control signal generation method according to an embodiment of the instant disclosure.

### DETAILED DESCRIPTION

The foregoing and other technical contents, features, and effects of the instant disclosure can be clearly presented below in detailed description with reference to embodiments of the accompanying drawings. Thicknesses or sizes of the elements in the drawings illustrated in an exaggerated, omitted, or general manner are used to help a person skilled in the art to understand and read, and the size of each element is not the completely actual size and is not intended to limit restraint conditions under which the instant disclosure can be implemented and therefore have no technical significance. Any modification to the structure, change to the proportional relationship, or adjustment on the size without affecting the effects and the objectives that can be achieved by the instant disclosure should fall within the scope of the technical content disclosed by the instant disclosure. In the following detailed description, the term “connect” may refer to any means of direct or indirect connection.

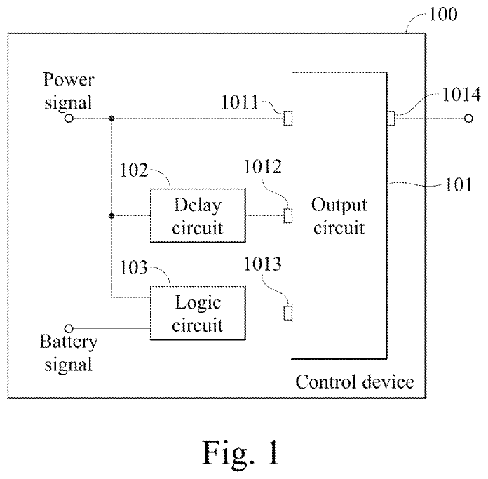

FIG. 1 illustrates a schematic block diagram of a control device according to an embodiment of the instant disclosure. Please refer to FIG. 1. The control device 100 comprises an output circuit 101, a delay circuit 102, and a logic circuit 103. The delay circuit 102 is configured to receive a power signal and generate a delay signal based on the power signal. When the power signal is changed from a first level voltage to a second level voltage, the delay signal reaches the second level voltage later than the power signal. The first level voltage is different from the second level voltage. For example, the first level voltage and second level voltage may be a high voltage representing logical 1 and a low voltage representing logical 0, respectively. In other words, in this embodiment, the first level voltage may be the high voltage representing logical 1, and the second level voltage may be the low voltage representing logical 0. Of course, the first level voltage may also be the low voltage representing logical 0, while the second level voltage may be the high voltage representing logical 1, and the instant disclosure is not limited thereto. The high voltage representing logical 1 and the low voltage representing logical 0 are usually presented by two different voltages and allow some errors. For example, taking 2 volts (V) as the low voltage representing logical 0 and 3 V as the high voltage representing logical 1, a voltage from 0 V to 2 V also represents logical 0, and a voltage from 3 V to 5 V also represents logical 1. In this example, a voltage from 2 V to 3 V is invalid and will only appear during logic change or malfunctioning.

The logic circuit 103 receives the power signal and a battery signal. The logic circuit 103 is configured, so that an output end of the logic circuit 103 outputs a third level voltage in response to that one of the power signal and the battery signal (including simultaneously) is at the second level voltage. The logic circuit 103 is also configured, so that the output end of the logic circuit 103 outputs a fourth level voltage in response to that both of the power signal and the battery signal are at the first level voltage. The third level voltage is different from the fourth level voltage. For example, the third level voltage and fourth level voltage may be the high voltage representing logical 1 and the low voltage representing logical 0, respectively.

In some embodiments of the instant disclosure, the first level voltage is the low voltage representing logical 0, the second level voltage is the high voltage representing logical 1, the third level voltage is the high voltage representing logical 1, and the fourth level voltage is the low voltage representing logical 0. In these embodiments, the logic circuit 103 outputs the high voltage representing logical 1 in response to that one of the power signal and the battery signal is at the high voltage representing logical 1, and the logic circuit 103 outputs the low voltage representing logical 0 in response to that both of the power signal and the battery signal are at the low voltage representing logical 0. This operation of the logic circuit 103 is an OR operation.

The output circuit 101 comprises a first end 1011, a second end 1012, a third end 1013, and an output end 1014. The first end 1011 receives the power signal. The second end 1012 receives the delay signal. The third end 1013 is connected to the output end of the logic circuit 103 to receive the output signal of the output end of the logic circuit 103. The output end 1014 has a current state Q₀. The current state Q₀ may be the high voltage or the low voltage. When the output circuit 101 does not generate a new output to update the current state Q₀, the output end 1014 maintains the current state Q₀. The output circuit 101 is configured to execute the following: in response to that the third end 1013 receives the third level voltage, outputting a level voltage that is identical to the level voltage received by the first end 1011 when the second end 1012 is changed from the first level voltage to the second level voltage. In other words, in this embodiment, when the second end 1012 is changed from the first level voltage to the second level voltage, if the first end 1011 receives the high voltage representing logical 1, the output circuit 101 outputs the high voltage representing logical 1 from the output end 1014 to replace the current state Q₀, and the output circuit 101 maintains the current state Q₀ at the high voltage until the next output of the output circuit 101 is outputted; and if the first end 1011 receives the low voltage representing logical 0, the output circuit 101 outputs the low voltage representing logical 0 from the output end 1014 to replace the current state Q₀, and the output circuit 101 maintains the current state Q₀ at the low voltage until the next output of the output circuit 101 is outputted. The output circuit 101 also outputs a stopping voltage in response to that the third end 1013 receives the fourth level voltage. The stopping voltage may be the high voltage representing logical 1 or the low voltage representing logical 0, depending on the interaction setting of the control device 100 and other external electronic devices.

The operation of the output circuit 101 may be represented by Table I.

TABLE I

| Input | | | Output end |
|---|---|---|---|
| Third end 1013 | Second end 1012 | First end 1011 | 1014 |
| Third level | First level voltage | First level | First level |
| voltage | → Second level | voltage | voltage |
| | voltage | | |
| Third level | First level voltage | Second level | Second level |
| voltage | → Second level | voltage | voltage |
| | voltage | | |
| Third level | First level voltage | × | Current state |
| voltage | or Second level | | Q₀ |
| | voltage | | |
| Fourth level | × | × | Stopping |
| voltage | | | voltage |

In Table I, the symbol X indicates that the condition of the first level voltage or the second level voltage does not influence the output end 1014.

The following will explain the control signal generation method and how the various modules of the control device 100 cooperate with one another in detail with reference to the drawings.

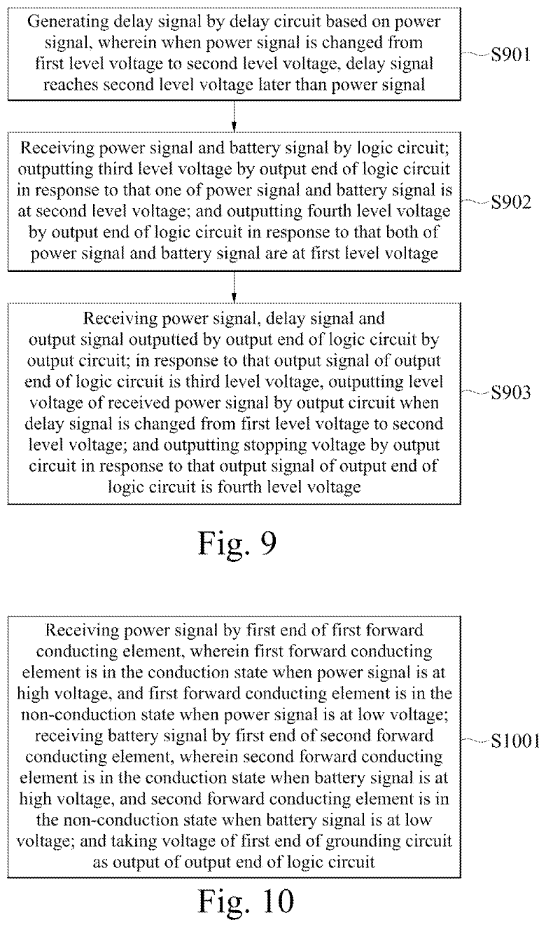

FIG. 9 illustrates a schematic flow chart of the control signal generation method according to an embodiment of the instant disclosure. As a person having ordinary skill in the art understand, the control signal generation method of the instant disclosure is not limited to being applied to the control device 100 shown in FIG. 1 and is not limited to being executed in the order of the steps of the flow chart shown in FIG. 9. Refer to FIG. 1 and FIG. 9 at the same time. In the step S901, the delay circuit 102 generates the delay signal based on the power signal, wherein when the power signal is changed from the first level voltage to the second level voltage, the delay signal reaches the second level voltage later than the power signal. In the step S902, the logic circuit 103 receives the power signal and the battery signal, wherein an output end of the logic circuit 103 outputs the third level voltage in response to that one of the power signal and the battery signal is at the second level voltage; and the output end of the logic circuit 103 outputs the fourth level voltage in response to that both of the power signal and the battery signal are at the first level voltage. It is noted that the order for executing the step S901 and the step S902 is not limited, and the step S901 and the step S902 may be executed at the same time.

In the step S903, the output circuit 101 receives the power signal, the delay signal, and an output signal of the output end of the logic circuit 103. In response to that the output signal of the output end of the logic circuit 103 is the third level voltage, the output circuit 101 outputs a level voltage of the received power signal when the delay signal is changed from the first level voltage to the second level voltage. The output circuit 101 outputs the stopping voltage in response to that the output signal of the output end of the logic circuit 103 is the fourth level voltage.

To further illustrate, the power signal may be received by the first end 1011 of the output circuit 101, the delay signal may be received by the second end 1012 of the output circuit 101, and the output of the output end of the logic circuit 103 may be received by the third end 1013 of the output circuit 101. In response to that the third end 1013 receives the third level voltage, the output circuit 101 outputs the level voltage received at the first end 1011 when the second end 1012 is changed from the first level voltage to the second level voltage. In response to that the third end 1013 receives the fourth level voltage, the output circuit 101 outputs the stopping voltage.

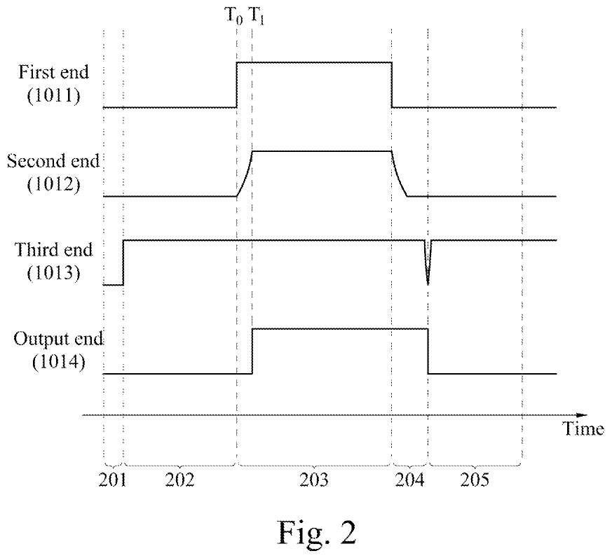

FIG. 2 illustrates an operation sequence diagram of a control device according to an embodiment of the instant disclosure. The following will illustrate the operation of the control device 100 with reference to FIG. 2. In the embodiment shown in FIG. 2, the first level voltage, the fourth level voltage, and the stopping voltage are each set to be the low voltage, the second level voltage and the third level voltage are each set to be the high voltage, and the current state Q₀ is initially the low voltage. Under this setting, the operation of the output circuit 101 may be represented in the following Table II.

TABLE II

| Input | | | | Output end |
|---|---|---|---|---|
| Third end 1013 | | Second end 1012 | First end 1011 | 1014 |
| (1) | High voltage | Low voltage | Low voltage | Low voltage |
| | | → High voltage | | |
| (2) | High voltage | Low voltage | High voltage | High voltage |
| | | → High voltage | | |
| (3) | High voltage | Low voltage | × | Current state |
| | | or High voltage | | Q₀ |
| (4) | Low voltage | × | × | Low voltage |

In Table II, the symbol X indicates that the condition of the high voltage or the low voltage does not influence the output end 1014. The mechanism in which the output end 1014 outputs the level voltage received by the first end 1011 when the second end 1012 of the output circuit 101 is changed from the low voltage to the high voltage is referred to as positive edge trigger. Similarly, the mechanism in which the output end 1014 outputs the level voltage received by the first end 1011 when the second end 1012 of the output circuit 101 is changed from the high voltage to the low voltage is referred to as negative edge trigger.

Refer to FIG. 2. During the time interval 201, the power signal received by the first end 1011 is the low voltage, the delay signal received by the second end 1012 is the low voltage, and the battery signal received by the logic circuit 103 is the low voltage. Therefore, the output end of the logic circuit 103 outputs the low voltage, and the third end 1013 of the output circuit 101 consequently receives the low voltage. In this case, according to the operation of item (4) in Table II, the output circuit 101 outputs the low voltage from the output end 1014.

During the time interval 202, the power signal received by the first end 1011 is the low voltage, the delay signal received by the second end 1012 is the low voltage, and the battery signal received by the logic circuit 103 is the high voltage. Therefore, the output end of the logic circuit 103 outputs the high voltage, and the third end 1013 of the output circuit 101 consequently receives the high voltage. In this case, according to the operation of item (3) in Table II, the output end 1014 of the output circuit 101 is maintained at the current state Q₀, which is the low voltage in this case.

During the time interval 203, the power signal received by the first end 1011 is the high voltage at time T₀, and the delay signal received by the second end 1012 is changed from the low voltage to the high voltage during the time interval from time T₀ to time T₁. The battery signal received by the logic circuit 103 is the high voltage. Therefore, the output end of the logic circuit 103 outputs the high voltage, and the third end 1013 of the output circuit 101 consequently receives the high voltage. In this case, according to the operation of item (2) in Table II, the output circuit 101 outputs the level voltage, which is the high voltage in this case, received by the first end 1011 from the output end 1014 at time T₁. After time T₁ and until the time point when the time interval 203 ends, because the output of the logic circuit 103 received by the third end 1013 of the output circuit 101 is not changed, according to the operation of item (3) in Table II, the output end 1014 of the output circuit 101 is maintained at the current state Q₀, which is the high voltage in this case.

During the time interval 204, the power signal received by the first end 1011 is changed from the high voltage to the low voltage, and the battery signal received by the logic circuit 103 is the high voltage. Therefore, the output end of the logic circuit 103 outputs the high voltage, and the third end 1013 of the output circuit 101 consequently receives the high voltage. Because the second end 1012 is not changed from the low voltage to the high voltage, according to the operation of item (3) in Table II, the output end 1014 of the output circuit 101 is maintained at the current state Q₀, which is the high voltage in this case.

During the time interval 205, at the beginning of the time interval 205, the battery signal exhibits a bounce, and therefore the output end of the logic circuit 103 drops to the low voltage momentarily. In this case, according to the operation of item (4) in Table II, the output end 1014 of the output circuit 101 outputs the low voltage as the stopping voltage. After the starting time of the time interval 205, even though the output end of the logic circuit 103 has been restored to the high voltage, because the second end is not changed from the low voltage to the high voltage, according to the operation of item (3) in Table II, the output end 1014 of the output circuit 101 is maintained at the current state Q₀, which is the low voltage in this case, as the stopping voltage.

The operation illustrated in FIG. 2 may be applied to the control of battery discharge. The battery signal may be generated based on the battery usage signal generated by the output voltage of the battery. When unstable power supply of the battery is detected through the bouncing of the battery signal, the output end 1014 of the output circuit 101 outputs the outputting voltage (which is the low voltage in this embodiment).

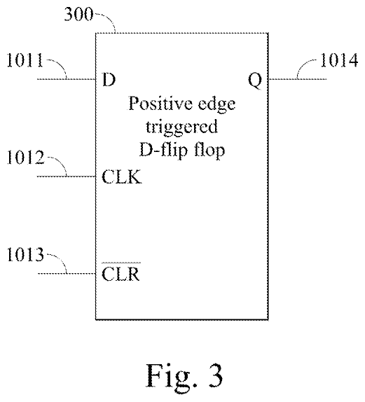

FIG. 3 illustrates a schematic block diagram of an output circuit according to an embodiment of the instant disclosure. Refer to FIG. 3. In the embodiment shown in FIG. 3, the first level voltage, the fourth level voltage, and the stopping voltage are set to be the low voltage, the second level voltage and the third level voltage are set to be the high voltage, and the current state Q₀ is initially the low voltage. In this embodiment, the output circuit 101 comprises a positive edge triggered D-flip flop 300. A signal input end (denoted by D in FIG. 3) of the positive edge triggered D-flip flop 300 is set as the first end 1011 of the output circuit 101. A clock input end (denoted by CLK in FIG. 3) of the positive edge triggered D-flip flop 300 is set as the second end 1012 of the output circuit 101. A clear end (denoted by C̅L̅R̅ in FIG. 3) of the positive edge triggered D-flip flop 300 is set as the third end 1013 of the output circuit 101. An output end (denoted by Q in FIG. 3) of the positive edge triggered D-flip flop 300 is set as the output end 1014 of the output circuit 101.

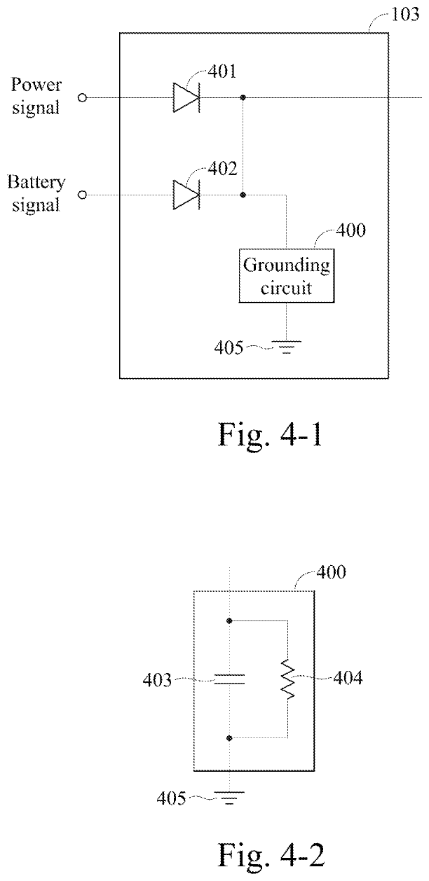

FIG. 4-1 illustrates a schematic circuit diagram of a logic circuit according to an embodiment of the instant disclosure. Refer to FIG. 4-1. In the embodiment shown in FIG. 4-1, the first level voltage and the fourth level voltage are set to be the low voltage, and the second level voltage and the third level voltage are set to be the high voltage. In this embodiment, the logic circuit 103 comprises a forward conducting element 401 (referred to as the first forward conducting element hereinafter for easy illustration), a forward conducting element 402 (referred to as the second forward conducting element hereinafter for easy illustration), and a grounding circuit 400. In this embodiment, a first end of the first forward conducting element receives the power signal. When the power signal is at the high voltage, the first forward conducting element is in the conduction state, so that the power signal can pass through the first forward conducting element. When the power signal is at the low voltage, the first forward conducting element is in the non-conduction state, so that the power signal cannot pass through the first forward conducting element. A first end of the second forward conducting element receives the battery signal. When the battery signal is at the high voltage, the second forward conducting element is in the conduction state, so that the battery signal can pass through the second forward conducting element. When the battery signal is at the low voltage, the second forward conducting element is in the non-conduction state, so that the battery signal cannot pass through the second forward conducting element.

A second end of the first forward conducting element is connected to the output end of the logic circuit 103, and the second end of the first forward conducting element is connected to a second end of the second forward conducting element, the third end 1013 of the output circuit 101, and a first end of the grounding circuit 400. A second end of the grounding circuit 400 is connected to a ground end 405. When one of the power signal and the battery signal is at the high voltage, one of the first forward conducting element and the second forward conducting element is in the conduction state, and therefore the output of the logic circuit 103 outputs the high voltage. When both of the power signal and the battery signal are at the low voltage, the output end of the logic circuit 103 outputs the low voltage. A voltage of the first end of the grounding circuit 400 is taken as the output of the output end of the logic circuit 103.

FIG. 4-2 illustrates a schematic circuit diagram of a logic circuit according to an embodiment of the instant disclosure. Refer to FIG. 4-2. In some embodiments of the instant disclosure, the grounding circuit 400 comprises a resistive element 404 and a capacitive element 403. A first end of the capacitive element 403 and a first end of the resistive element 404 are connected to the first end of the grounding circuit 400. A second end of the capacitive element 403 and a second end of the resistive element 404 are connected to the second end of the grounding circuit 400. In other words, in this embodiment, the grounding circuit 400 comprises the resistive element 404 and the capacitive element 403 which are connected in parallel. A voltage of the first end of the resistive element 404 is taken as the output of the output end of the logic circuit 103. In this embodiment, the capacitive element 403 can reduce the interference of noises on the output of the output end of the logic circuit 103.

The resistive element 404 may be implemented using a single resistor, or using multiple resistors connected in series and/or parallel, or using other electronic components able to generate resistance. The capacitive element 403 may be implemented using a single capacitor or using multiple capacitors connected in series and/or parallel. The first forward conducting element is a diode (referred to as a first diode hereinafter for easy illustration), an anode of the first diode is taken as the first end of the first forward conducting element, and a cathode of the first diode is taken as the second end of the first forward conducting element. The second forward conducting element is a diode (referred to as a second diode hereinafter for easy illustration), an anode of the second diode is taken as the first end of the second forward conducting element, and a cathode of the second diode is taken as the second end of the second forward conducting element.

FIG. 10 illustrates a schematic flow chart of a control signal generation method according to an embodiment of the instant disclosure. Refer to FIG. 4 and FIG. 10 at the same time. In the embodiment shown in FIG. 10, the step S902 comprises a step S1001. In the step S1001, the first end of the first forward conducting element receives the power signal, wherein when the power signal is at the high voltage, the first forward conducting element is in the conduction state, and when the power signal is at the low voltage, the first forward conducting element is in the non-conduction state; the first end of the second forward conducting element receives the battery signal, wherein when the battery voltage is at the high voltage, the second forward conducting element is in the conduction state, and when the battery signal is at the low voltage, the second forward conducting element is in the non-conduction state; and the voltage of the first end of the grounding circuit 400 is taken as the output of the output end of the logic circuit 103.

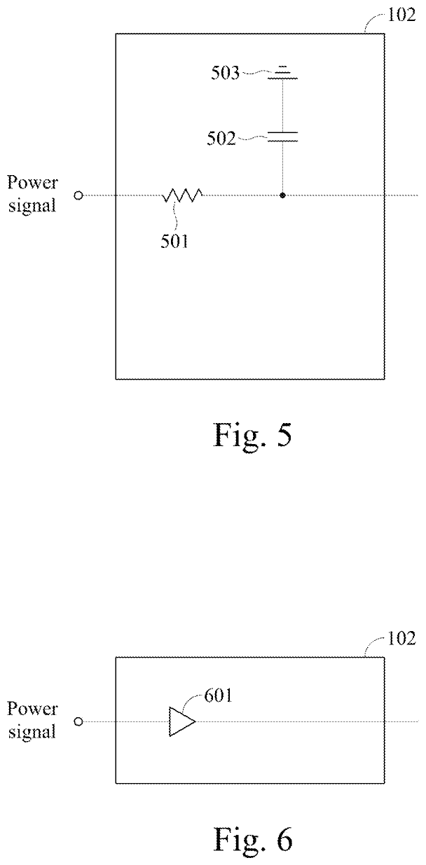

FIG. 5 illustrates a schematic circuit diagram of a delay circuit according to an embodiment of the instant disclosure. Refer to FIG. 1 and FIG. 5 at the same time. In the embodiment shown in FIG. 5, the first level voltage is set to be the low voltage, and the second level voltage is set to be the high voltage. In this embodiment, the delay circuit 102 comprises a resistive element 501 and a capacitive element 502. A first end of the resistive element 501 receives the power signal, a second end of the resistive element 501 is connected to the output end of the delay circuit 102, and the second end of the resistive element 501 is also connected to a first end of the capacitive element 502 and the second end 1012 of the output circuit 101. A second end of the capacitive element 502 is connected to a ground end 503. The capacitive element 502 receives the power signal through the resistive element 501. Through this circuit configuration, a capacitor voltage signal of the first end of the capacitive element 502 is taken as the delay signal and outputted to the second end 1012 of the output circuit 101. Because the power signal charges the capacitive element 502 when the power signal is changed from the low voltage to the high voltage, the capacitor voltage signal of the first end of the capacitive element 502 reaches the high voltage later than the power signal. The capacitive element 502 may be implemented using a single capacitor or using multiple capacitors connected in series and/or parallel.

In some embodiments of the instant disclosure, the step S901 further comprises the following step: taking the capacitor voltage signal of the first end of the capacitive element 502 which receives the power signal as the delay signal.

FIG. 6 illustrates a schematic circuit diagram of a delay circuit according to an embodiment of the instant disclosure. Refer to FIG. 1 and FIG. 6 at the same time. In the embodiment shown in FIG. 6, the delay circuit 102 comprises a buffer gate element 601. A first end of the buffer gate element 601 receives the power signal, and a second end of the buffer gate element 601 is connected to the second end 1012 of the output circuit 101. The buffer gate element 601 may be implemented by using a single buffer gate or using multiple buffer gates connected in series and/or parallel. Because a buffer gate can delay signals, the buffer gate element 601 can be used to delay the power signal in order to obtain the delay signal.

In some embodiments of the instant disclosure, the step S901 further comprises the following step: outputting a buffer gate output voltage signal by the second end of the buffer gate element 601 which receives the power signal as the delay signal.

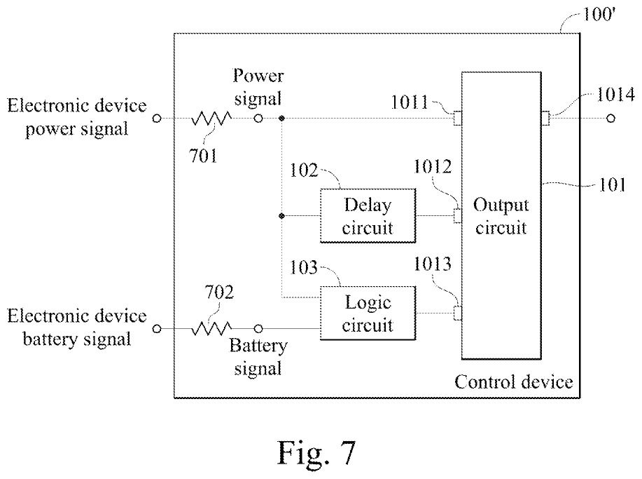

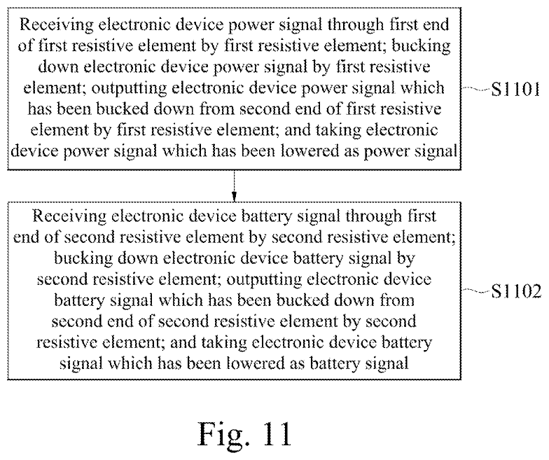

FIG. 7 illustrates a schematic block diagram of a control device according to an embodiment of the instant disclosure. Refer to FIG. 1 and FIG. 7 at the same time. Compared with FIG. 1, the control device 100′ shown in FIG. 7 further comprises a resistive element 701 (referred to as a first resistive element hereinafter for easy illustration) and a resistive element 702 (referred to as a second resistive element hereinafter for easy illustration). FIG. 11 illustrates a schematic flow chart of a control signal generation method, which can be applied to the control device 100′ shown in FIG. 7, according to an embodiment of the instant disclosure. Refer to FIG. 7 and FIG. 11 at the same time. In the embodiment shown in FIG. 11, the control signal generation method comprises a step S1101 and a step S1102. In the step S1101, the first resistive element receives an electronic device power signal from the exterior through a first end of the first resistive element, the first resistive element bucks down the electronic device power signal and outputs the electronic device power signal which has been bucked down from a second end of the first resistive element, and the first resistive element takes the electronic device power signal which has been bucked down as the power signal. The electronic device power signal may be a signal of an external power source into which an electronic device using the control device 100′ is plugged. The first resistive element can buck down the signal of the external power source into which the electronic device using the control device 100′ is plugged. This signal can be bucked down to be within a voltage range that is processable by the control device 100′.

In the step S1102, the second resistive element receives an electronic device battery signal through a first end of the second resistive element, the second resistive element bucks down the electronic device battery signal and outputs the electronic device battery signal which has been bucked down from a second end of the second resistive element, and the second resistive element takes the electronic device battery signal which has been bucked down as the battery signal. The electronic device battery signal may be a battery monitor signal of the electronic device using the control device 100′. The second resistive element can buck down the battery monitor signal of the electronic device using the control device 100′. This signal can be bucked down to be within the voltage range that is processable by the control device 100′. It is noted that the control signal generation method shown in FIG. 9 is applicable to the control device 100′ shown in FIG. 7, and the step S1101 and the step S1102 shown in FIG. 11 may be executed before the step S901 shown in FIG. 9.

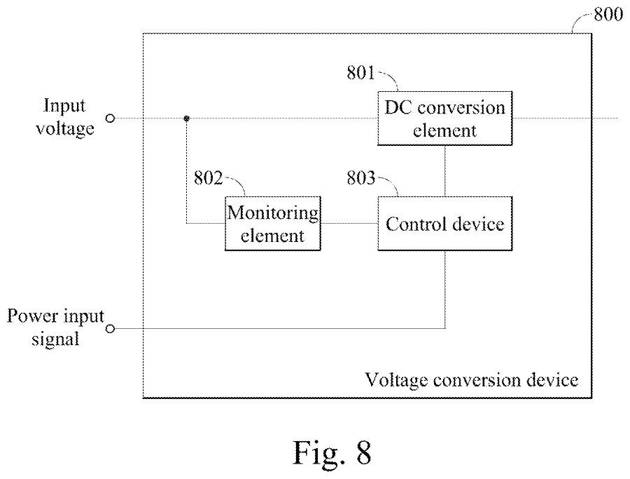

FIG. 8 illustrates a schematic diagram of a voltage conversion device according to an embodiment of the instant disclosure. Refer to FIG. 8. The voltage conversion device 800 comprises a DC conversion element 801, a monitoring element 802, and a control device 803. The monitoring element 802 is configured to monitor whether a battery of an electronic device is supplying power, and the monitoring device 802 is configured to output a battery usage signal based on an output voltage of the battery of the electronic device. The monitoring element 802 may be implemented using a voltage monitoring chip in order to detect the output voltage provided by the battery of the electronic device, so that when the battery of the electronic device is supplying power, the monitoring element 802 outputs a voltage level, and when the battery of the electronic device is not supplying power, the monitoring element 802 outputs another voltage level as the battery usage signal.

The control device 803 may adopt any of the control devices 100, 100′ in the aforementioned embodiments. That is, in one or some embodiments, the control device 803 comprises the output circuit 101, the delay circuit 102, and the logic circuit 103 shown in FIG. 1, or the control device 803 comprises the output circuit 101, the delay circuit 102, the logic circuit 103, and the resistive elements 701, 702 shown in FIG. 7.

The DC conversion element 801 is configured to convert the output voltage provided by the battery in response to that the output circuit 101 of the control device 803 outputs a voltage level which is not the stopping voltage (and referred to as a starting voltage hereinafter for easy illustration) and stop converting the output voltage provided by the battery in response to that the output circuit 101 of the control device 803 outputs the stopping voltage. In this embodiment, the control device 803 generates the battery signal based on the battery usage signal and generates the power signal based on a power input signal of the electronic device.

In some embodiments of the instant disclosure, the control device 803 takes the power input signal of the electronic device as the electronic device power signal and uses the first resistive element to buck down the electronic device power signal in order to generate the power signal; and the control signal 803 takes the battery usage signal as the electronic device battery signal and uses the second resistive element to buck down the electronic device battery signal in order to generate the battery signal.

In some embodiments of the instant disclosure, the DC conversion element 801 is a boost converter. The boost converter may adopt a boost converter chip having an enable input pin, and the output end 1014 of the output circuit 101 may be connected to the enable input pin, so that when the output circuit 101 of the control device 803 outputs the starting voltage, the boost converter chip converts the output voltage provided by the battery; and when the output circuit 101 of the control device 803 outputs the stopping voltage, the boost converter chip stops converting the output voltage provided by the battery.

As above, by using sequential circuits which integrate the power signal, the power signal processed by the circuits, and the battery signal, the control device, the control signal generation method, and the voltage conversion device provided by some embodiments of the instant disclosure can generate control signals to timely stop the battery from supplying power using a simple circuit structure in order to maintain overall stability of an electronic system.

Although the technical context of the instant disclosure has been disclosed with the preferred embodiments above, the embodiments are not meant to limit the instant disclosure. Any adjustment and retouch done by any person skill in the art without deviating from the spirit of the instant disclosure shall be covered by the scope of the instant disclosure. Therefore, the protected scope of the instant disclosure shall be defined by the attached claims.

What is claimed is:

1. A control device, comprising:
a delay circuit configured to generate a delay signal based on a power signal, wherein when the power signal is changed from a first level voltage to a second level voltage, the delay signal reaches the second level voltage later than the power signal;
a logic circuit configured to receive the power signal and a battery signal, wherein an output end of the logic circuit outputs a third level voltage in response to that one of the power signal and the battery signal is at the second level voltage, and the output end of the logic circuit outputs a fourth level voltage in response to that both of the power signal and the battery signal are at the first level voltage; and
an output circuit configured to receive the power signal, the delay signal, and an output signal of the output end of the logic circuit, wherein in response to that the output signal of the output end of the logic circuit is the third level voltage, when the delay signal is changed from the first level voltage to the second level voltage, the output circuit outputs a level voltage of the power signal which is received, and the output circuit outputs a stopping voltage in response to that the output signal of the output end of the logic circuit is the fourth level voltage.

2. The control device according to claim 1, wherein the output circuit comprises a first end, a second end, and a third end, the first end receives the power signal, the second end receives the delay signal, and the third end is connected to the output end of the logic circuit to receive the output signal of the output end of the logic circuit.

3. The control device according to claim 2, wherein the first level voltage, the fourth level voltage, and the stopping voltage are each a low voltage, and the second level voltage and the third voltage are each a high voltage.

4. The control device according to claim 3, wherein the output circuit is a positive edge triggered D-flip flop, a signal input end of the positive edge triggered D-flip flop is the first end, a clock input end of the positive edge triggered D-flip flop is the second end, and a clear end of the positive edge triggered D-flip flop is the third end.

5. The control device according to claim 3, wherein the logic circuit comprises a first forward conducting element, a second forward conducting element, and a grounding circuit; a first end of the first forward conducting element receives the power signal, the first forward conducting element is in a conduction state when the power signal is at the high voltage, and the first forward conducting element is in a non-conduction state when the power signal is at the low voltage; a first end of the second forward conducting element receives the battery signal, the second forward conducting element is in the conduction state when the battery signal is at the high voltage, and the second forward conducting element is in the non-conduction state when the battery signal is at the low voltage; a second end of the first forward conducting element is connected to a second end of the second forward conducting element, the third end of the output circuit, and a first end of the grounding circuit, and a second end of the grounding circuit is connected to a ground end; and a voltage of the first end of the grounding circuit is taken as an output of the output end of the logic circuit.

6. The control device according to claim 5, wherein the grounding circuit comprises a resistive element and a capacitive element, a first end of the capacitive element and a first end of the resistive element are connected to the first end of the grounding circuit, and a second end of the capacitive element and a second end of the resistive element are connected to the second end of the grounding circuit.

7. The control device according to claim 5, wherein the first forward conducting element is a first diode, an anode of the first diode is the first end of the first forward conducting element, and a cathode of the first diode is the second end of the first forward conducting element; and the second forward conducting element is a second diode, an anode of the second diode is the first end of the second forward conducting element, and a cathode of the second diode is the second end of the second forward conducting element.

8. The control device according to claim 2, wherein the first level voltage is a low voltage, the second level voltage is a high voltage, the delay circuit comprises a resistive element and a capacitive element, a first end of the resistive element receives the power signal, a second end of the resistive element is connected to a first end of the capacitive element and the second end of the output circuit, and a second end of the capacitive element is connected to a grounding end.

9. The control device according to claim 2, wherein the delay circuit comprises a buffer gate element, a first end of the buffer gate element receives the power signal, and a second end of the buffer gate element is connected to the second end of the output circuit.

10. The control device according to claim 1, further comprising a first resistive element and a second resistive element, wherein the first resistive element receives an electronic device power signal through a first end of the first resistive element, bucks down the electronic device power signal, and outputs the electronic device power signal which has been bucked down from a second end of the first resistive element as the power signal; the second resistive element receives an electronic device battery signal through a first end of the second resistive element, bucks down the electronic device battery signal, and outputs the electronic device battery signal which has been bucked down from a second end of the second resistive element as the battery signal.

11. A voltage conversion device, comprising the control device according to claim 1, wherein the voltage conversion device further comprises:
a monitoring element configured to monitor whether a battery of an electronic device is supplying power and output a battery usage signal based on an output voltage of the battery of the electronic device; and
a DC conversion element configured to convert the output voltage provided by the battery in response to that the output circuit of the control device outputs a starting voltage and stop converting the output voltage provided by the battery in response to that the output circuit of the control device outputs the stopping voltage; wherein the control device generates the battery signal based on the battery usage signal, and the control device generates the power signal based on a power input signal of the electronic device.

12. The voltage conversion device according to claim 11, wherein the DC conversion element is a boost converter.

13. A control signal generation method, adapted for a control device comprising a delay circuit, a logic circuit, and an output circuit, wherein the control signal generation method comprises:
(a) generating a delay signal by the delay circuit based on a power signal, wherein when the power signal is changed from a first level voltage to a second level voltage, the delay signal reaches the second level voltage later than the power signal;
(b) receiving the power signal and a battery signal by the logic circuit; outputting a third level voltage by an output end of the logic circuit in response to that one of the power signal and the battery signal is at the second level voltage; and outputting a fourth level voltage by the output end of the logic circuit in response to that both of the power signal and the battery signal are at the first level voltage; and
(c) receiving the power signal, the delay signal, and an output signal outputted by the output end of the logic circuit by the output circuit; in response to that the output signal of the output end of the logic circuit is the third level voltage, when the delay signal is changed from the first level voltage to the second level voltage, outputting a level voltage of the power signal which is received by the output circuit; and outputting a stopping voltage by the output circuit in response to that the output signal of the output end of the logic circuit is the fourth level voltage.

14. The control signal generation method according to claim 13, wherein the output circuit comprises a first end, a second end, and a third end, the third end is connected to the output end of the logic circuit, and the step (c) comprises receiving the power signal by the first end, receiving the delay signal by the second end, and receiving the output signal of the output end of the logic circuit by the third end.

15. The control signal generation method according to claim 14, wherein the first level voltage, the fourth level voltage and the stopping voltage are each a low voltage, and the second level voltage and the third voltage are each a high voltage.

16. The control signal generation method according to claim 15, wherein the logic circuit comprises a first forward conducting element, a second forward conducting element, and a grounding circuit, a second end of the first forward conducting element is connected to a second end of the second forward conducting element, the third end of the output circuit and a first end of the grounding circuit, a second end of the grounding circuit is connected to a ground end, and the step (b) comprises: receiving the power signal by a first end of the first forward conducting element, wherein the first forward conducting element is in a conduction state when the power signal is at the high voltage, and the first forward conducting element is in a non-conduction state when the power signal is at the low voltage; receiving the battery signal by a first end of the second forward conducting element, wherein the second forward conducting element is in the conduction state when the battery signal is at the high voltage, and the second forward conducting element is in the non-conduction state when the battery signal is at the low voltage; and taking a voltage of the first end of the grounding circuit as an output of the output end of the logic circuit.

17. The control signal generation method according to claim 16, wherein the grounding circuit comprises a resistive element and a capacitive element, a first end of the capacitive element and a first end of the resistive element are connected to the first end of the grounding circuit, a second end of the capacitive element and a second end of the resistive element are connected to the second end of the grounding circuit, and the step (b) comprises: taking a voltage of the first end of the resistive element as the voltage of the first end of the grounding circuit.

18. The control signal generation method according to claim 14, wherein the first level voltage is a low voltage, the second level voltage is a high voltage, the delay circuit comprises a resistive element and a capacitive element, a first end of the resistive element receives the power signal, a second end of the resistive element is connected to a first end of the capacitive element and the second end of the output circuit, a second end of the capacitive element is connected to a grounding end, the capacitive element receives the power signal through the resistive element, and the step (a) comprises: taking a capacitor voltage signal of the first end of the capacitive element which receives the power signal as the delay signal.

19. The control signal generation method according to claim 14, wherein the delay circuit comprises a buffer gate element, a first end of the buffer gate element receives the power signal, a second end of the buffer gate element is connected to the second end of the output circuit, and the step (a) comprises: taking a buffer gate output voltage signal of the second end of the buffer gate element which receives the power signal as the delay signal.

20. The control signal generation method according to claim 13, wherein the control device comprises a first resistive element and a second resistive element, and the control signal generation method comprises:
receiving an electronic device power signal through a first end of the first resistive element by the first resistive element; bucking down the electronic device power signal by the first resistive element; outputting the electronic device power signal which has been bucked down from a second end of the first resistive element by the first resistive element as the power signal; and
receiving an electronic device battery signal through a first end of the second resistive element by the second resistive element, bucking down the electronic device battery signal by the second resistive element, outputting the electronic device battery signal which has been bucked down from a second end of the second resistive element by the second resistive element as the battery signal.
